(19) United States
(12) Patent Application Publication
(10) Pub. No.: US 2019/0244793 A1
(43) Pub. Date: Aug. 8, 2019

(54) TAPERED UPPER ELECTRODE FOR UNIFORMITY CONTROL IN PLASMA PROCESSING

(71) Applicant: Lam Research Corporation, Fremont, CA (US)

(72) Inventors: Zhigang Chen, Campbell, CA (US); Alexei Marakhtanov, Albany, CA (US); John Holland, San Jose, CA (US); Pratik Jacob Mankidy, Fremont, CA (US); Anthony Dela Llera, Fremont, CA (US); Haley Kim, Fremont, CA (US); Hyungjoo Shin, Fremont, CA (US)

(21) Appl. No.: 15/888,719

(22) Filed: Feb. 5, 2018

(51) Int. Cl. H01J 37/32; C23C 16/455

(52) U.S. Cl. CPC H01J 37/32541; H01J 37/3244; H01L 21/67069; H01J 2237/334; C23C 16/45565

(57) ABSTRACT

An upper electrode for use in a substrate processing system includes a lower surface. The lower surface includes a first portion and a second portion and is plasma-facing. The first portion includes a first surface region that has a first thickness. The second portion includes a second surface region that has a varying thickness such that the second portion transitions from a second thickness to the first thickness.

### FIELD

The present disclosure relates to systems and methods for controlling process uniformity in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, dielectric etch, rapid thermal processing (RTP), ion implant, physical vapor deposition (PVD), and/or other etch, deposition, or cleaning processes. A substrate may be arranged on a substrate support, such as a pedestal, an electrostatic chuck (ESC), etc. in a processing chamber of the substrate processing system. During processing, gas mixtures may be introduced into the processing chamber and plasma may be used to initiate and sustain chemical reactions.

The processing chamber includes various components including, but not limited to, the substrate support, a gas distribution device (e.g., a showerhead, which may also correspond to an upper electrode), a plasma confinement shroud, etc. The substrate support may include a ceramic layer arranged to support a wafer. For example, the wafer may be clamped to the ceramic layer during processing. The substrate support may include an edge ring arranged around an outer portion (e.g., outside of and/or adjacent to a perimeter) of the substrate support. The edge ring may be provided to confine plasma to a volume above the substrate, optimize substrate edge processing performance, protect the substrate support from erosion caused by the plasma, etc. The plasma confinement shroud may be arranged around each of the substrate support and the showerhead to further confine the plasma within the volume above the substrate.

### SUMMARY

An upper electrode for use in a substrate processing system includes a lower surface. The lower surface includes a first portion and a second portion and is plasma-facing. The first portion includes a first surface region that has a first thickness. The second portion includes a second surface region that has a varying thickness such that the second portion transitions from a second thickness to the first thickness.

In other features, the second thickness corresponds to a height of the second portion at a center of the upper electrode. The first portion has a first radius, the second portion has a second radius, and the first radius is greater than the second radius. The second radius corresponds to a third radius of an electric field generated below the upper electrode during operation of the substrate processing system. The second radius is greater than or equal to the third radius.

In other features, the second surface region is sloped such that the second portion tapers from the second thickness to the first thickness. A slope of the second portion corresponds to an electric field generated below the upper electrode during operation of the substrate processing system. The second surface region is stepped. The second surface region is curved. The second surface region is convex. The second surface region is piecewise linear. Vertices and corners of the upper electrode are rounded by a radius of 0.5 mm-10 mm. The lower surface further comprises a plurality of holes configured to allow process gases to flow from a gas distribution device through the upper electrode.

In other features, a gas distribution device includes the upper electrode. The gas distribution device corresponds to a showerhead. A substrate processing system includes the gas distribution device.

A gas distribution device for use in a substrate processing system includes a stem portion and a base portion including an upper electrode. The upper electrode includes a lower surface. The lower surface includes a first portion and a second portion and is plasma-facing. The first portion has a first thickness and includes a first surface region that is flat. The second portion includes a second surface region that has a varying thickness such that the second portion transitions from a second thickness to the first thickness.

In other features, the second surface region is sloped such that the second portion tapers from the second thickness to the first thickness. The second surface region is stepped. The second surface region is curved. The second surface region is convex. The second surface region is piecewise linear. Vertices and corners of the upper electrode are rounded by a radius of 0.5 mm-10.0 mm.

An upper electrode for use in a substrate processing system includes a first portion having a first surface region and a second portion that extends beyond the first surface region and is symmetrically located with respect to a center of the upper electrode. The second portion has an apex and an outer periphery and is tapered from the apex toward the outer periphery.

In other features, the first surface region is flat and/or concave. The apex is aligned with the center of the upper electrode. The first portion has a first radius, the second portion has a second radius, and the first radius is greater than the second radius. The second radius corresponds to a third radius of an electric field generated below the upper electrode during operation of the substrate processing system. The second radius is greater than or equal to the third radius.

In other features, a slope of the second portion corresponds to an electric field generated below the upper electrode during operation of the substrate processing system. The second portion is at least one of stepped, curved, convex, and piecewise linear. The first and second portions are substrate-facing. At least one of the first and second portions further comprises a plurality of holes configured to allow process gases to flow from a gas distribution device through the upper electrode.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example substrate processing system according to the principles of the present disclosure;

FIG. 2 is an example substrate processing chamber;

FIG. 3 is a substrate processing chamber including an example upper electrode according to the principles of the present disclosure;

FIG. 4 is a substrate processing chamber including another example upper electrode according to the principles of the present disclosure; and

FIGS. 5A, 5B, and 5C are example upper electrodes according to the principles of the present disclosure.

FIGS. 6A and 6B are example upper electrodes according to the principles of the present disclosure.

In the drawings, reference numbers may be reused to identify similar and/or identical elements.

### DETAILED DESCRIPTION

Some aspects of etch processing may vary in accordance with characteristics of a substrate processing system, a substrate, gas mixtures, temperature, radio frequency (RF) and RF power, etc. For example, flow patterns, and therefore etch rate and etch uniformity, may vary according to dimensions of components within a processing chamber of the substrate processing system. In some example processes, overall etch rates vary as the distance between an upper surface of the substrate and a bottom surface of a gas distribution device increases. Further, the etch rates may vary from the center of the substrate to an outer perimeter of the substrate. For example, at an outer perimeter of the substrate, sheath bending and ion incidence angle tilt can cause high aspect ratio contact (HARC) profile tilt, plasma density drop can cause etch rate and etch depth roll off, and chemical loading associated with reactive species (e.g., etchants and/or deposition precursors) can cause feature critical dimension (CD) non-uniformity. Further, material such as etch by-products can be re-deposited on the substrate. Etch rates may vary according to other process parameters including, but not limited to, RF and RF power, temperature, and gas flow velocities across the upper surface of the substrate.

Components that may affect processing of the substrate include, but are not limited to, a gas distribution device (e.g., a showerhead, which may also correspond to an upper electrode), a plasma confinement shroud, and/or a substrate support including a baseplate, one or more edge rings, coupling rings, etc. For example, dielectric plasma etching processes may use an upper electrode having a flat bottom surface facing plasma. In some applications, a high radio frequency (RF) source power (e.g., an RF source power provided at 60 MHz, 40 MHz, etc.) may cause a center-peaked plasma distribution in a processing volume above the substrate. Further, a high bias power (e.g., a bias power provided at 400 kHz, 2 MHz, etc.) may cause a plasma density peak in an edge region (e.g., an edge peak between 80-150 mm from a center) of the substrate. A plasma distribution including a center peak and an edge peak may be referred to as a “W”-shaped radial plasma non-uniformity.

Accordingly, non-uniform plasma distribution may cause non-uniform processing results (e.g., etching). In some applications (e.g., high aspect ratio etching applications), the radial plasma non-uniformity may result in profile tilting in addition to etch non-uniformity across the substrate. As the aspect ratio increases (e.g., an aspect ratio greater than 50), tolerance for profile tilting decreases and very small tilting (e.g., less than 0.1°) may be desired.

Systems and methods according to the principles of the present disclosure modify dimensions and geometry (e.g., a profile) of the upper electrode to control radial plasma distribution and uniformity. For example, an upper electrode having a tapered (i.e., angled, sloped, tilted, curved, shaped, etc.), plasma-facing lower surface is used. In one example, the upper electrode tapers from a center in a radial direction toward an outer perimeter of the upper electrode. In some examples, the tapering may not extend to the outer perimeter of the upper electrode and instead may discontinue at a distance radially inward of the outer perimeter. In other examples, the tapering may extend to the outer perimeter of the upper electrode. Accordingly, the thickness of the upper electrode varies based on a radial distance from a center of the upper electrode.

Dimensions of the tapering (e.g., respective thicknesses at a radial distance of the upper electrode, a radius or length of the tapering, etc.) may be selected according to a desired radial plasma distribution. For example, the thickness of the tapering may be determined according to a peak plasma density at the center of the upper electrode. Conversely, the radius or length of the tapering may be determined according to a length scale of a radial plasma density gradient. The thickness of the tapering at the center of the upper electrode is selected to reduce and eliminate the peak plasma density in the center of the processing volume, while the radius or length of the tapering is selected to reduce (i.e., smooth out) and minimize plasma non-uniformity in the radial direction. Accordingly, profile tilting and etch non-uniformity caused by plasma non-uniformity in high aspect ratio etching may be minimized.

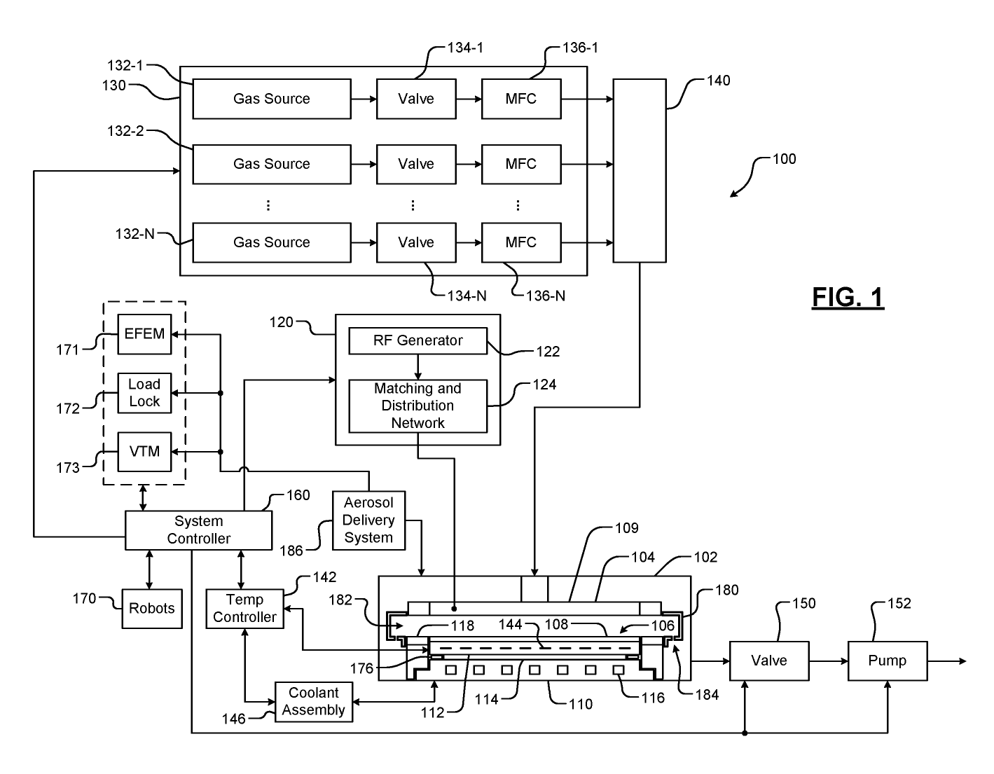

Referring now to FIG. 1, an example substrate processing system 100 is shown. For example only, the substrate processing system 100 may be used for performing etching using RF plasma, deposition, and/or other suitable substrate processing. The substrate processing system 100 includes a processing chamber 102 that encloses other components of the substrate processing system 100 and contains the RF plasma. The substrate processing chamber 102 includes an upper electrode 104 and a substrate support 106, such as an electrostatic chuck (ESC). During operation, a substrate 108 is arranged on the substrate support 106. While a specific substrate processing system 100 and chamber 102 are shown as an example, the principles of the present disclosure may be applied to other types of substrate processing systems and chambers.

For example only, the upper electrode 104 may include a gas distribution device such as a showerhead 109 that introduces and distributes process gases. The showerhead 109 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode 104 may include a conducting plate and the process gases may be introduced in another manner. The upper electrode 104 according to the principles of the present disclosure may have a tapered, plasma-facing lower surface as described below in more detail.

The substrate support 106 includes a conductive baseplate 110 that acts as a lower electrode. The baseplate 110 supports a ceramic layer 112. In some examples, the ceramic layer 112 may comprise a heating layer, such as a ceramic multi-zone heating plate. A thermal resistance layer 114 (e.g., a bond layer) may be arranged between the ceramic layer 112 and the baseplate 110. The baseplate 110 may include one or more coolant channels 116 for flowing coolant through the baseplate 110. The substrate support 106 may include an edge ring 118 arranged to surround an outer perimeter of the substrate 108.

An RF generating system 120 generates and outputs RF power to one of the upper electrode 104 and the lower electrode (e.g., the baseplate 110 of the substrate support 106). The other one of the upper electrode 104 and the baseplate 110 may be DC grounded, RF grounded or floating. For example only, the RF generating system 120 may include an RF power generator 122 that generates the RF power that is fed by a matching and distribution network 124 to the upper electrode 104 or the baseplate 110. In other examples, the plasma may be generated inductively or remotely. Although, as shown for example purposes, the RF generating system 120 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more gas mixtures. The gas sources may also supply purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 109.

A temperature controller 142 may be connected to a plurality of heating elements, such as thermal control elements (TCEs) 144 arranged in the ceramic layer 112. For example, the heating elements 144 may include, but are not limited to, macro heating elements corresponding to respective zones in a multi-zone heating plate and/or an array of micro heating elements disposed across multiple zones of a multi-zone heating plate. The temperature controller 142 may be used to control the plurality of heating elements 144 to control a temperature distribution of the substrate support 106 and the substrate 108.

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106.

A valve 150 and pump 152 may be used to evacuate etch byproducts from the processing chamber 102. A system controller 160 may be used to control components of the substrate processing system 100. One or more robots 170 may be used to deliver substrates onto, and remove substrates from, the substrate support 106. For example, the robots 170 may transfer substrates between an EFEM 171 and a load lock 172, between the load lock and a VTM 173, between the VTM 173 and the substrate support 106, etc. Although shown as separate controllers, the temperature controller 142 may be implemented within the system controller 160. In some examples, a protective seal 176 may be provided around a perimeter of the bond layer 114 between the ceramic layer 112 and the baseplate 110.

In some examples, the processing chamber 102 may include a plasma confinement shroud 180, such as a C-shroud. The C-shroud 180 is arranged around the upper electrode 104 and the substrate support 106 to confine plasma within a plasma region 182. In some examples, the C-shroud 180 comprises a semiconductor material, such as silicon (Si) or polysilicon. The C-shroud 180 may include one or more slots 184 arranged to allow gases to flow out of the plasma region 182 to be vented from the processing chamber 102 via the valve 150 and the pump 152.

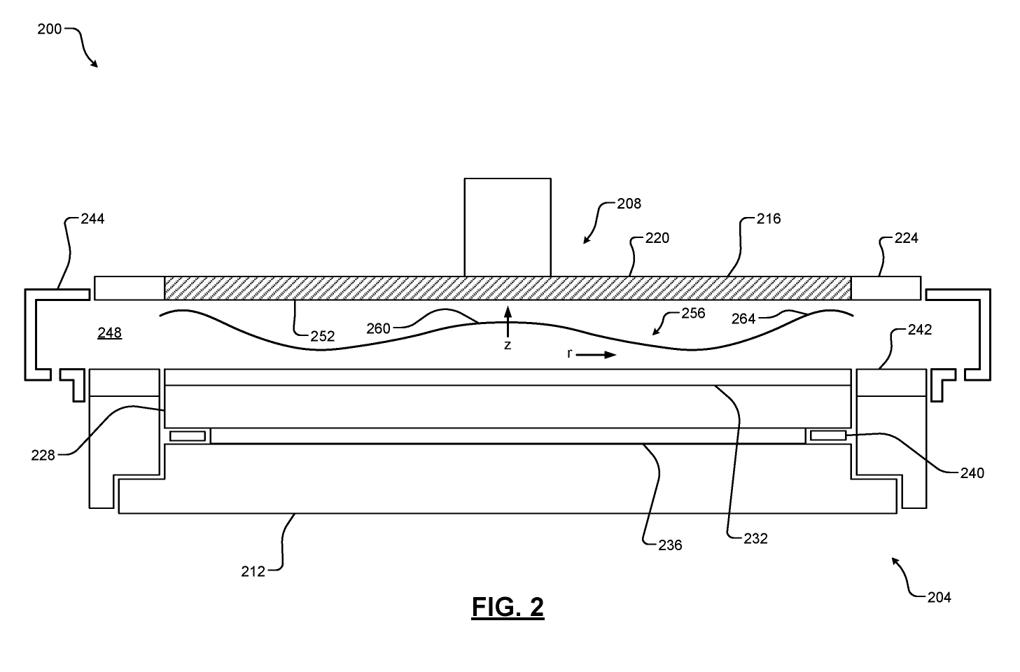

Referring now to FIG. 2, an example substrate processing chamber 200 including a substrate support 204 and a gas distribution device 208 (e.g., a showerhead) is shown. The substrate support 204 includes a baseplate 212 that may function as a lower electrode. Conversely, the gas distribution device 208 may include an upper electrode 216. In some examples, the upper electrode 216 may include an inner electrode 220 and an outer electrode 224. For example, the inner electrode 220 and the outer electrode 224 may correspond to a disc and annular ring, respectively (i.e., the outer electrode 224 surrounds an outer edge of the inner electrode 220). As used herein for simplicity, the present disclosure will refer to the inner electrode 220 and the outer electrode 224 collectively as the upper electrode 216.

The baseplate 212 supports a ceramic layer 228. The ceramic layer 228 supports a substrate 232. In some examples, a bond layer 236 is arranged between the ceramic layer 228 and the baseplate 212 and a protective seal 240 is provided around a perimeter of the bond layer 236 between the ceramic layer 228 and the baseplate 212. The substrate support 204 may include an edge ring 242 arranged to surround an outer perimeter of the substrate 232. In some examples, the processing chamber 200 may include a plasma confinement shroud 244 arranged around the upper electrode 216. The upper electrode 216, the substrate support 204 (e.g., the ceramic layer 228), the edge ring 242, and the plasma confinement shroud 244 define a processing volume (e.g., a plasma region) 248 above the substrate 232.

As shown in FIG. 2, a lower surface 252 of the upper electrode 216 is substantially flat and plasma-facing. For example, the lower surface 252 is planar, has a horizontal orientation relative to the processing chamber 200, and is parallel to the substrate 232 and the ceramic layer 228. As shown at 256, the upper electrode 216 having the flat lower surface 252 results in a center-peaked plasma density distribution (“plasma distribution”). Accordingly, the plasma distribution is non-uniform and includes a center peak 260 (i.e., a density peak in a vertical z direction centered with respect to the processing volume 248 and the upper electrode 216) and may decrease in an r direction (i.e., a radial direction). The plasma distribution may further include an outer peak 264. The plasma distribution shown in FIG. 2 may result in processing non-uniformities, such as profile tilting of the substrate 232 (e.g., in a mid-radius region of the substrate 232) and etch non-uniformity.

For example, the plasma distribution is caused by a corresponding RF electric field (E-field) distribution and its power deposition into plasma. The E-field distribution is dependent upon an effective RF wavelength in the generated plasma corresponding to the applied RF, and therefore the E-field distribution is generally correlated to the plasma distribution. For example, in FIG. 2, the E-field distribution may be similar to the plasma distribution shown at 256. Accordingly, the E-field distribution may be greater in a region corresponding to the center peak 260 of the plasma distribution and decrease in the r direction (i.e., as the radius increases). In other words, the E-field distribution exhibits radial decay over some distance.

In CCP systems, the RF power used to generate the plasma generates a capacitive component Ez of the E-field distribution in the vertical direction, which causes capacitive plasma heating. Accordingly, capacitive plasma heating is increased in the region of the center peak 260 of the plasma distribution when the effective RF wavelength is near or smaller than the substrate radius. Conversely, an inductive component Er of the E-field distribution in the radial direction is essentially zero in the region of the center peak 260. In other words, an E-field distribution corresponding to the plasma distribution shown in FIG. 2 may correspond to E=Ez, where Er=0 in the region of the center peak 260.

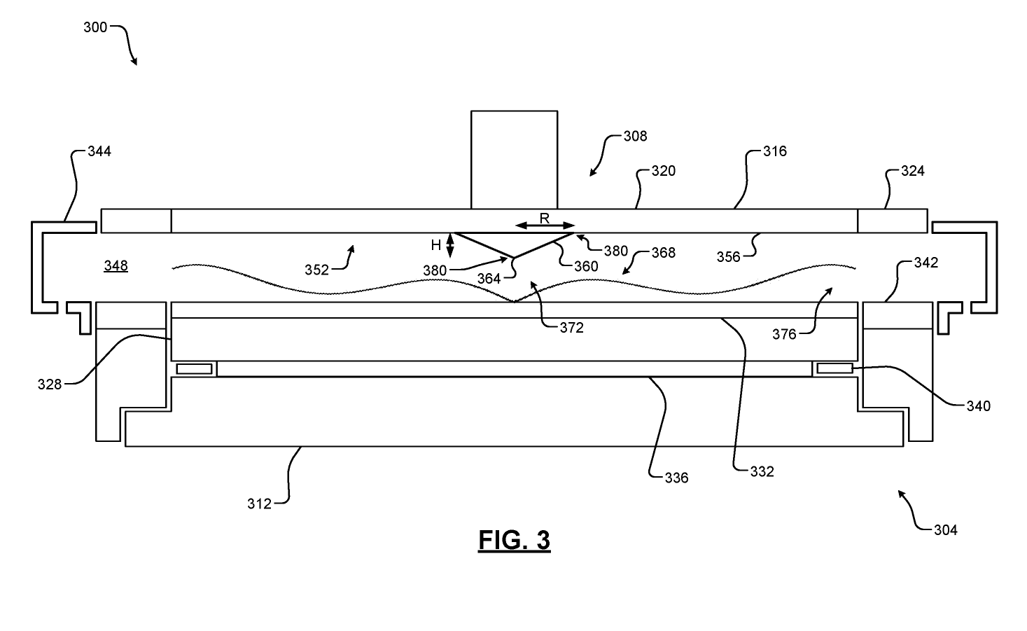

Referring now to FIG. 3, another example substrate processing chamber 300 including a substrate support 304 and a gas distribution device 308 (e.g., a showerhead) is shown. The substrate support 304 includes a baseplate 312 that may function as a lower electrode. Conversely, the gas distribution device 308 may include an upper electrode 316. In some examples, the upper electrode 316 may include an inner electrode 320 and an outer electrode 324. For example, the inner electrode 320 and the outer electrode 324 may correspond to a concentric disc and ring, respectively (i.e., the outer electrode 324 surrounds an outer edge of the inner electrode 320). As used herein for simplicity, the present disclosure will refer to the inner electrode 320 and the outer electrode 324 collectively as the upper electrode 316.

The baseplate 312 supports a ceramic layer 328. The ceramic layer 328 supports a substrate 332. In some examples, a bond layer 336 is arranged between the ceramic layer 328 and the baseplate 312 and a protective seal 340 is provided around a perimeter of the bond layer 336 between the ceramic layer 328 and the baseplate 312. The substrate support 304 may include an edge ring 342 arranged to surround an outer perimeter of the substrate 332. In some examples, the processing chamber 300 may include a plasma confinement shroud 344 arranged around the upper electrode 316. The upper electrode 316, the substrate support 304 (e.g., the ceramic layer 328), the edge ring 342, and the plasma confinement shroud 344 define a processing volume (e.g., a plasma region) 348 above the substrate 332.

As shown in FIG. 3, a lower surface 352 of the upper electrode 316 is tapered and plasma-facing. For example, the lower surface 352 includes a first portion 356 that has a first thickness and is generally flat and a tapered (i.e., sloped) second portion 360. The second portion 360 decreases from a height H at a center 364 of the lower surface 352 as a radius R (i.e., a distance from the center 364) increases. Accordingly, a thickness of the second portion 360 varies (e.g., decreases) as radius increases. As shown at 368, the upper electrode 316 having the tapered lower surface 352 suppresses a center peak of the plasma distribution. In other words, the plasma distribution as shown in FIG. 3 does not include the center peak 260 as shown in FIG. 2. Further, the tapered second portion 360 facilitates plasma diffusion from a small gap area (i.e., in a center region 372) to a large gap area (i.e., in an outer region 376) and therefore lowers plasma density in the center region 372.

In contrast to the example of FIG. 2, the tapered lower surface 352 results in a reduced capacitive E-field component Ez in the vertical direction and generation of a non-zero inductive E-field component Er in the radial direction in the center region 372. The inductive component Er contributes to inductive plasma heating, which is efficient in plasma generation. Further, the inductive component Er increases as the radius R increases. Accordingly, since the inductive component Er increases with radius and the capacitive component Ez decreases with radius, the inductive component Er compensates for variation in plasma distribution and heating caused by the decrease in the capacitive component Ez. In other words, an E-field E corresponding to the plasma distribution shown in FIG. 3 may correspond to E=Ez+Er, which combines both the capacitive component Ez and the inductive component Er and therefore leads to a more uniform plasma distribution with the center peak suppressed.

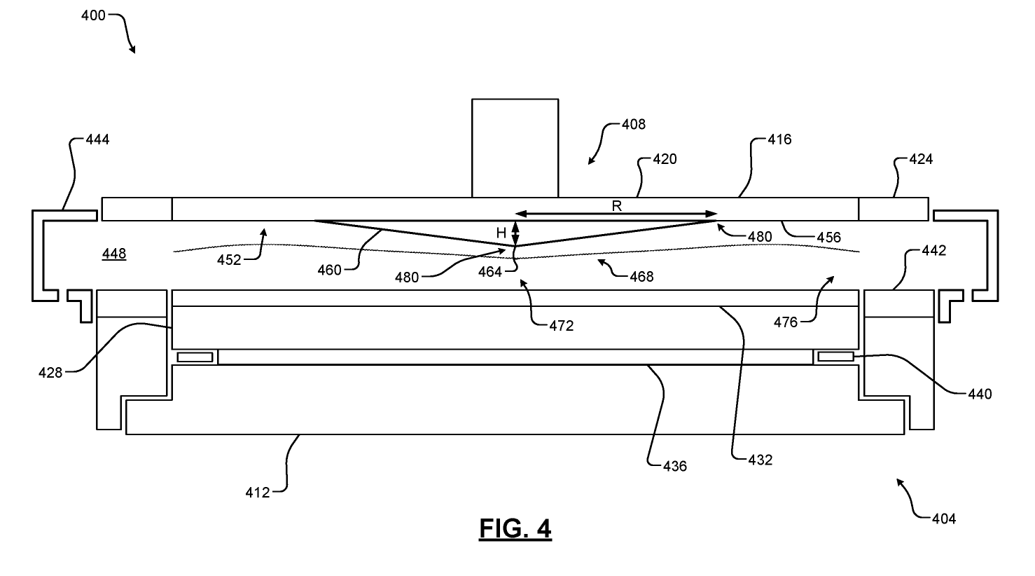

Referring now to FIG. 4, another example substrate processing chamber 400 including a substrate support 404 and a gas distribution device 408 (e.g., a showerhead) is shown. The substrate support 404 includes a baseplate 412 that may function as a lower electrode. Conversely, the gas distribution device 408 may include an upper electrode 416. In some examples, the upper electrode 416 may include an inner electrode 420 and an outer electrode 424. For example, the inner electrode 420 and the outer electrode 424 may correspond to a concentric disc and ring, respectively (i.e., the outer electrode 424 surrounds an outer edge of the inner electrode 420). As used herein for simplicity, the present disclosure will refer to the inner electrode 420 and the outer electrode 424 collectively as the upper electrode 416.

The baseplate 412 supports a ceramic layer 428. The ceramic layer 428 supports a substrate 432. In some examples, a bond layer 436 is arranged between the ceramic layer 428 and the baseplate 412 and a protective seal 440 is provided around a perimeter of the bond layer 436 between the ceramic layer 428 and the baseplate 412. The substrate support 404 may include an edge ring 442 arranged to surround an outer perimeter of the substrate 432. In some examples, the processing chamber 400 may include a plasma confinement shroud 444 arranged around the upper electrode 416. The upper electrode 416, the substrate support 404 (e.g., the ceramic layer 428), the edge ring 442, and the plasma confinement shroud 444 define a processing volume (e.g., a plasma region) 448 above the substrate 432.

As shown in FIG. 4, a lower surface 452 of the upper electrode 416 is tapered and plasma-facing. For example, the lower surface 452 includes a first portion 456 that has a first thickness and is generally flat and a tapered (i.e., sloped) second portion 460. The second portion 460 decreases from a height H at a center 464 of the lower surface 452 as a radius R (i.e., a distance from the center 464) increases. Accordingly, a thickness of the second portion 460 varies (e.g., decreases) as radius increases. As shown at 468, the upper electrode 416 having the tapered lower surface 452 suppresses a center peak of the plasma distribution. In other words, the plasma distribution as shown in FIG. 4 does not include the center peak 260 as shown in FIG. 2. Further, the tapered second portion 460 facilitates plasma diffusion from a small gap area (i.e., in a center region 472) to a large gap area (i.e., in an outer region 476) and therefore lowers plasma density in the center region 472.

Similar to the example of FIG. 3, the tapered lower surface 452 results in a reduced capacitive E-field component Ez in the vertical direction and generation of a non-zero inductive E-field component Er in the radial direction in the center region 472. Accordingly, since the inductive component Er increases with radius and the capacitive component Ez decreases with radius, the inductive component Er compensates for variation in plasma distribution and heating caused by the decrease in the capacitive component Ez. In contrast to the example of FIG. 3, the taper of the second portion 460 has a smaller slope and is more gradual than the taper of the second portion 360 (i.e., the thickness of the second portion 460 decreases at a lower rate or angle as radius increases). Accordingly, plasma density uniformity and profile tilting across the substrate 432 are improved.

As shown in FIGS. 3 and 4, dimensions (e.g., a height H, a radius R, an angle of the slope, etc.) of the second portions 360 and 460 may be selected according to characteristics of the E-field and plasma distribution in the respective processing chambers 300 and 400. For example, the height H of the second portions 360 and 460 may be selected according to a maximum magnitude of the E-field and plasma density in the center regions 372 and 472. Conversely, the radius R of the second portions 360 and 460 may be selected according to a radius of the corresponding E-field and plasma density gradient. In one example, the radius R may be greater than or equal to a length scale of the E-field and a plasma radial gradient. For example, if the radial decay of the E-field and plasma density reaches a trough at 75 mm, the radius R of the second portion 360 or 460 may be at least 75 mm. In other examples, respective slopes of the second portions 360 and 460 may correspond to slopes of the E-field and plasma density. In other words, as the E-field and plasma density decay radially, the height H of the second portion 360 or 460 may decrease radially in proportion to the E-field and plasma density decay.

In this manner, dimensions of the upper electrodes 316/416 may be selected according to operating characteristics of a specific processing chamber. For example, characteristics such as plasma distribution, E-field, etc. may be first observed and measured (e.g., with a conventional upper electrode installed). Dimensions of an upper electrode according to the principles of the present disclosure may then be determined based on the measured operating characteristics of the chamber. In some example, vertices and corners (e.g., angled transitions such as at vertices 380/480) of the upper electrodes 316/416 may be rounded by a radius of 0.5 mm-10.0 mm.

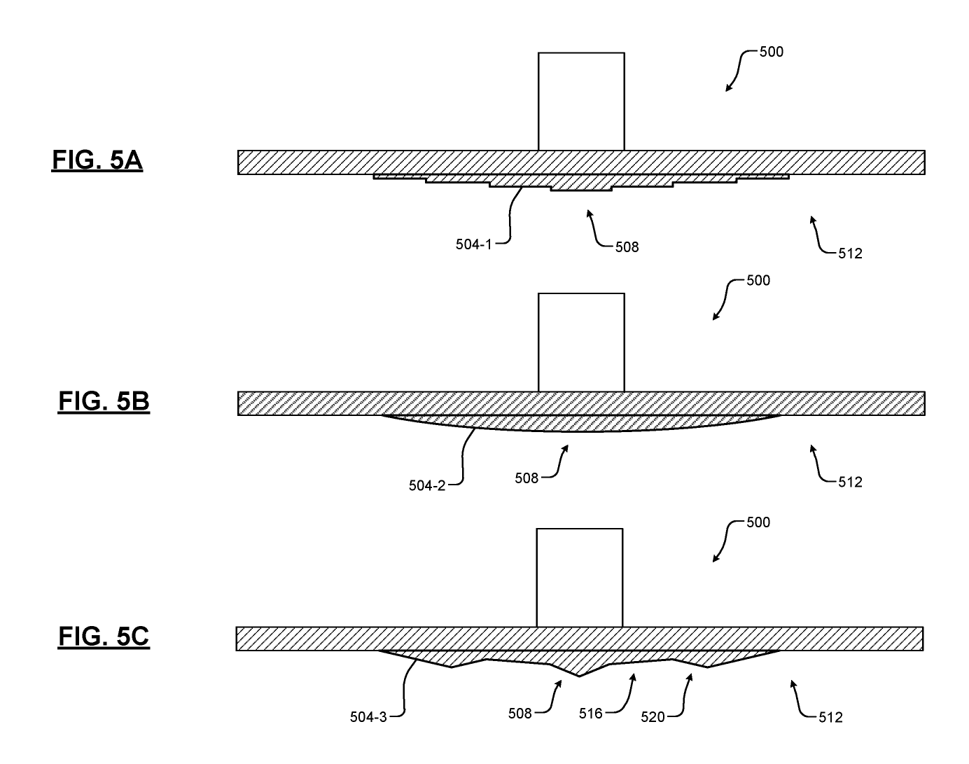

As shown in FIGS. 5A, 5B, and 5C, an upper electrode 500 may include other example lower surfaces 504-1, 504-2, and 504-3 (referred to collectively as the lower surfaces 504) configured to modify the plasma distribution. For example, as shown in FIG. 5A, the lower surface 504-1 of the upper electrode 500 may be stepped or stair cased. In other words, the lower surface 504-1 may have a thickness that decreases in a stepwise fashion from a center region 508 of the upper electrode 500 to an outer region 512 of the upper electrode. As shown in FIG. 5B, the lower surface 504-2 of the upper electrode 500 may be curved (e.g., convex). In other words, the lower surface 504-2 may have a thickness that decreases in a curvilinear fashion from a center region 508 of the upper electrode 500 to an outer region 512 of the upper electrode. As shown in FIG. 5C, the lower surface 504-3 may be angled or sloped in a piecewise linear fashion. In other words, the lower surface 504-3 may have a thickness that decreases and/or increases at different angles from the center region 508 of the upper electrode 500 to the outer region 512 of the upper electrode. For example, the thickness of the lower surface 504-3 may decrease at a first angle in the center region 508, decrease at a second angle in a mid-inner region 516, increase at a third angle in a mid-outer region 520, and decrease at a fourth angle in the outer region 12. Accordingly, the lower surfaces 504 may be selected and configured in accordance with plasma distribution characteristics in a particular substrate processing chamber. In some examples, vertices and corners of the upper electrode 500 and the lower surfaces 504 may be rounded by a radius of 0.5 mm-10.0 mm.

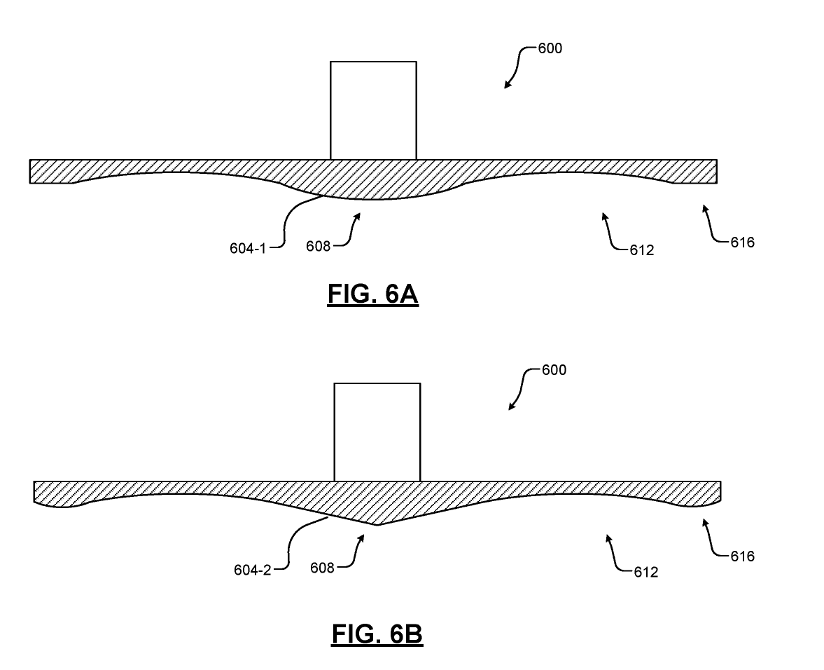

As shown in FIGS. 6A and 6B, an upper electrode 600 may include other example lower surfaces 604-1 and 604-2 (referred to collectively as the lower surfaces 604) configured to modify the plasma distribution. For example, as shown in FIG. 6A, the lower surface 604-1 of the upper electrode 600 may be curved (e.g., convex) in a center region 608 and concave in an outer region 612. In other words, the lower surface 604-1 transitions from the convex center region 608 to the concave outer region 612, and both the center region 608 and the concave region 612 vary in thickness. For example, the lower surface 604-1 may have a thickness that decreases in a curvilinear fashion from the center region 608 and into the outer region 612 and then increases from the outer region 612 to an edge region 616. In the edge region 616 shown in FIG. 6A, the lower surface 604-1 may be flat.

As shown in FIG. 6B, the lower surface 604-2 of the upper electrode 600 may be tapered (e.g., sloped) in the center region 608 and concave in the outer region 612. In other words, the lower surface 604-2 transitions from the tapered center region 608 to the concave outer region 612, and both the center region 608 and the concave region 612 vary in thickness. For example, the lower surface 604-2 may have a thickness that decreases in a linear fashion from the center region 608 and into the outer region 612 and then increases from the outer region 612 to an edge region 616. In the edge region 616 shown in FIG. 6B, the lower surface 604-1 may be convex, radiused, rounded, etc.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An upper electrode for use in a substrate processing system, the upper electrode comprising:
a lower surface, wherein the lower surface includes a first portion and a second portion and is plasma-facing,
wherein the first portion includes a first surface region that has a first thickness, and
wherein the second portion includes a second surface region that has a varying thickness such that the second portion transitions from a second thickness to the first thickness.

2. The upper electrode of claim 1, wherein the second thickness corresponds to a height of the second portion at a center of the upper electrode.

3. The upper electrode of claim 1, wherein the first portion has a first radius, the second portion has a second radius, and the first radius is greater than the second radius.

4. The upper electrode of claim 3, wherein the second radius corresponds to a third radius of an electric field generated below the upper electrode during operation of the substrate processing system.

5. The upper electrode of claim 4, wherein the second radius is greater than or equal to the third radius.

6. The upper electrode of claim 1, wherein the second surface region is sloped such that the second portion tapers from the second thickness to the first thickness.

7. The upper electrode of claim 6, wherein a slope of the second portion corresponds to an electric field generated below the upper electrode during operation of the substrate processing system.

8. The upper electrode of claim 1, wherein the second surface region is stepped.

9. The upper electrode of claim 1, wherein the second surface region is curved.

10. The upper electrode of claim 9, wherein the second surface region is convex.

11. The upper electrode of claim 1, wherein the second surface region is piecewise linear.

12. The upper electrode of claim 1, wherein vertices and corners of the upper electrode are rounded by a radius of 0.5 mm-10 mm.

13. The upper electrode of claim 1, wherein the lower surface further comprises a plurality of holes configured to allow process gases to flow from a gas distribution device through the upper electrode.

14. A gas distribution device comprising the upper electrode of claim 1.

15. The gas distribution device of claim 14, wherein the gas distribution device corresponds to a showerhead.

16. A substrate processing system comprising the gas distribution device of claim 14.

17. An upper electrode for use in a substrate processing system, the upper electrode comprising:
a first portion having a first surface region; and
a second portion that extends beyond the first surface region and is symmetrically located with respect to a center of the upper electrode, the second portion having an apex and an outer periphery, wherein the second portion is tapered from the apex toward the outer periphery.

18. The upper electrode of claim 17, wherein the first surface region is flat.

19. The upper electrode of claim 17, wherein the first surface region is concave.

20. The upper electrode of claim 17, wherein the apex is aligned with the center of the upper electrode.

21. The upper electrode of claim 17, wherein the first portion has a first radius, the second portion has a second radius, and the first radius is greater than the second radius.

22. The upper electrode of claim 21, wherein the second radius corresponds to a third radius of an electric field generated below the upper electrode during operation of the substrate processing system.

23. The upper electrode of claim 22, wherein the second radius is greater than or equal to the third radius

24. The upper electrode of claim 17, wherein a slope of the second portion corresponds to an electric field generated below the upper electrode during operation of the substrate processing system.

25. The upper electrode of claim 17, wherein the second portion is at least one of stepped, curved, convex, and piecewise linear.

26. The upper electrode of claim 17, wherein the first and second portions are substrate-facing.

27. The upper electrode of claim 17, wherein at least one of the first and second portions further comprises a plurality of holes configured to allow process gases to flow from a gas distribution device through the upper electrode.
